(19) United States
(12) Patent Application Publication
(10) Pub. No.: US 2009/0303809 A1
(43) Pub. Date: Dec. 10, 2009

(54) CIRCUIT AND METHOD FOR TERMINATING DATA LINE OF SEMICONDUCTOR INTEGRATED CIRCUIT

(75) Inventor: Kie Bong KU, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: Hynix Semiconductor Inc., Ichon (KR)

(21) Appl. No.: 12/345,471

(22) Filed: Dec. 29, 2008

(30) Foreign Application Priority Data
Jun. 4, 2008 (KR) 10-2008-0052703

(51) Int. Cl. G11C 7/00; G11C 5/14; G11C 8/18; G11C 8/00

(52) U.S. Cl. 365/193; 365/191; 365/226; 365/233.1; 365/230.06

(57) ABSTRACT

A data line termination circuit in a semiconductor integrated circuit includes a data line, a control unit for generating a termination control signal activated during a time section that includes a driving section in which data is driven to the data line, and a termination unit for terminating the data line to a predetermined voltage level in response to the termination control signal

### CROSS-REFERENCES TO RELATED APPLICATION

The present application claims priority under 35 U.S.C. §119(a) to Korean application number 10-2008-0052703, filed on Jun. 4, 2008, in the Korean Intellectual Property Office, which is incorporated herein by reference in its entirety as set forth in full.

### BACKGROUND

1. Technical Field

The embodiments described herein relate to a semiconductor integrated circuit (IC) and, more particularly, to a circuit having a terminated data line of a semiconductor IC and a method for terminating a data line of a semiconductor IC.

2. Related Art

FIG. 1 is a timing chart representing a conventional write operation in a semiconductor IC. In FIG. 1, when write command signals are sequentially applied to a semiconductor IC, data is input and arranged after a write latency (WL). In addition, a data clock signal ‘DCLK’ is issued in synchronization with a clock signal ‘CLK’ that is first generated after a time interval which is correspondent to a one-half of a burst length (BL).

In FIG. 1, drivability of global data lines GIO starts in synchronization with the data clock signal ‘DCLK’. For example, the global data lines GIO, which are maintained at a ground voltage (VSS) level or a power supply voltage (VDD) level, are transitioned to an opposite level when a rising edge of the data clock signal ‘DCLK’ is generated. As a result, the global data lines GIO swing in a CMOS level, i.e., within the whole range of the ground voltage (VSS) level to the power supply voltage (VDD) level.

The global data lines GIO are used as data transmission paths between DQ pads and a memory cell area in the semiconductor IC. The global data lines GIO include a plurality of lines that are adjacent to each other, and are made up of metal wires having large resistance and capacitance.

However, conventional semiconductor ICs are problematic that since the global data lines GIO swing between the ground voltage (VSS) level and the power supply voltage (VDD) level, the data transmission rate of the global data lines GIO is reduced due to the large resistance and capacitance. In addition, since the global data lines GIO swing between the ground voltage (VSS) level and the power supply voltage (VDD) level, cross talk characteristics severely deteriorate between the adjacent lines.

### SUMMARY

a circuit and a method for terminating a data line of a semiconductor IC capable of improving data transmission rate and reducing cross talk characteristics are described herein.

In one aspect, a data line termination circuit in a semiconductor integrated circuit includes a data line, a control unit for generating a termination control signal activated during a time section that includes a driving section in which data is driven to the data line, and a termination unit for terminating the data line to a predetermined voltage level in response to the termination control signal.

In another aspect, a data line termination circuit in a semiconductor integrated circuit includes a data line, a driver for driving the data line to a voltage level correspondent to input data received from an external circuit at a write operation, a control unit for generating a termination control signal activated during a time section that includes a driving section of the driver in which the data is driven to the data line, and a termination unit for terminating the data line to a predetermined voltage level in response to the termination control signal.

In another aspect, a data line termination circuit in a semiconductor integrated circuit includes a data line, a driver for driving the data line to a voltage level correspondent to data from a memory cell at a read operation, a control unit for generating a termination control signal activated during a time section that includes a driving section of the driver in which the data is driven to the data line, and a termination unit for terminating the data line to a predetermined voltage level in response to the termination control signal.

In another aspect, a data line termination circuit in a semiconductor integrated circuit includes a data line, a first driver for driving the data line to a voltage level correspondent to input data received from an external circuit at a write operation, a second driver for driving the data line to a voltage level correspondent to data from a memory cell at a read operation, a control unit for generating a termination control signal activated during a time section that includes a driving section of the first and second driver in which the data is driven to the data line, and a termination unit for terminating the data line to a predetermined voltage level in response to the termination control signal.

In another aspect, a method for terminating a data line in a semiconductor integrated circuit includes checking whether a write command signal or a read command signal is input, and terminating a data line to a predetermined voltage level during a time section that includes a driving section in which data are driven to the data line according to the write or read command signal when the write or read command signal is input.

In another aspect, s method for terminating a data line in a semiconductor integrated circuit, wherein the semiconductor integrated circuit includes a data line and a driver to drive the data line to a voltage level correspondent to input data received from an external circuit according to a write command signal, the method includes checking whether the write command signal is input, and terminating the data line to a predetermined voltage level before a driving operation of the driver when the write command signal is input.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a timing chart representing a conventional write operation in a semiconductor IC;

FIG. 2 is a schematic block diagram of an exemplary semiconductor IC according to one embodiment;

FIG. 3 is a schematic circuit diagram of an exemplary termination unit capable of being implemented in the semiconductor IC of FIG. 2 according to one embodiment;

FIG. 4 is a schematic circuit diagram of an exemplary control unit capable of being implemented in the semiconductor IC of FIG. 2 according to one embodiment; and

FIG. 5 is a timing chart representative of an exemplary write operation of a semiconductor IC according to one embodiment.

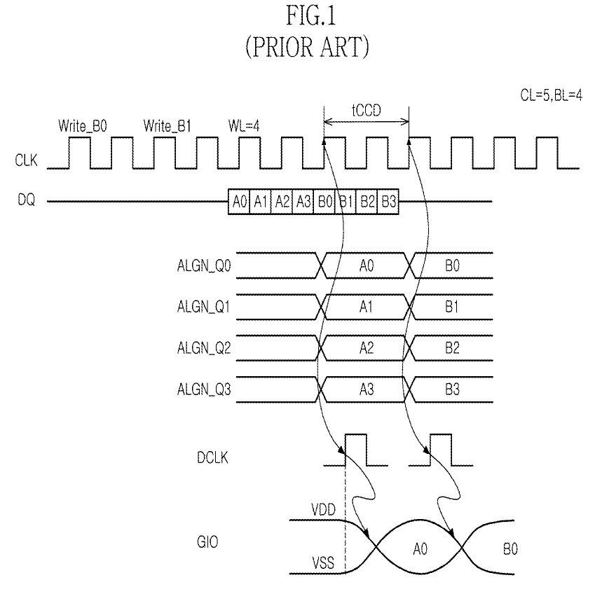

### DETAILED DESCRIPTION

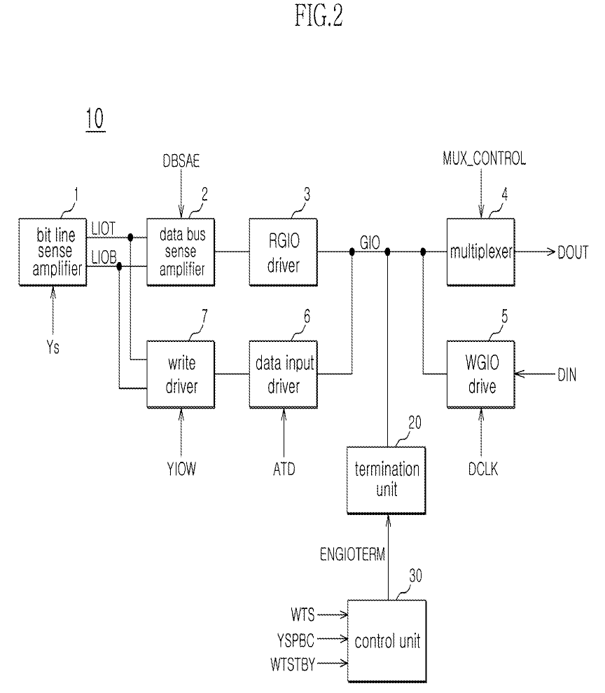

FIG. 2 is a schematic block diagram of an exemplary semiconductor IC according to one embodiment. In FIG. 2, a semiconductor IC can be configured to include a bit line sense amplifier 1, a data bus sense amplifier 2, a RGIO driver 3, a multiplexer 4, a WGIO drive 5, a data input driver 6, a write driver 7, a global data line GIO, a termination unit 20, and a control unit 30.

The bit line sense amplifier 1, which can be coupled between a memory cell of a core block and local data lines LIOT and LIOB, can sense and amplify input data signal when a column select signal ‘YS’ is activated. The data bus sense amplifier 2 can sense and amplify the data loaded on the local data lines LIOT and LIOB according to an enable signal ‘DBSAE’ at a read operation. The RGIO driver 3 can drive the global data line GIO at a voltage level, which can be correspondent to an output signal of the data bus sense amplifier 2, at the read operation.

At the read operation, the multiplexer 4 can selectively output, in compliance with a data output mode of x4, x8 or x16, the data loaded on the global data line GIO according to a multiplexing control signal ‘MUX_CONTROL’. The multiplexing control signal ‘MUX_CONTROL’ can be generated by an internal clock signal, which can be in synchronization with the column select signal ‘YS’ and the enable signal ‘DBSAE’, and can have a delay time compared with the enable signal ‘DBSAE’.

The WGIO driver 5 can drive the global data line GIO at a voltage level correspondent to input data that can be input according to a data clock signal ‘DCLK’ at a write operation. The data input driver 6 can drive and output the data loaded on the global data line GIO according to a control signal ‘ATD’ at the write operation. The write driver 7 can drive the local data lines LIOT and LIOB at a voltage level, which can be correspondent to an output signal of the data input driver 6, according to a control signal ‘YIOW’ at the write operation.

The termination unit 20 can be configured to terminate the global data line GIO to a predetermined voltage level (VDD/2) in response to an activation of a termination control signal ‘ENGIOTERM’.

The control unit 30 can be configured to generate the termination control signal ‘ENGIOTERM’ during the predetermined section’ including the driving section in which the data can be driven to the global data line GIO. In addition, the control unit 30 can determine the activation section of the termination control signal ‘ENGIOTERM’ according to a plurality of timing signals associated with the write or read operation. The plurality of the timing signals can include first to third signals ‘WTS’, ‘YSPBC’, and ‘WTSTBY’. The first signal ‘WTS’ can be provided to maintain the activation state, i.e., high level, while the write operation is performed. The second signal ‘YSPBC’ can be a pulse signal that can be produced according to the column address strobe signal, and the column select signal ‘YS’ can be produced by the second signal ‘YSPBC’. Here, the second signal ‘YSPBC’ can be in synchronization with a clock signal ‘CLK’ that can be generated with time lapse of WL+BL/2 after the write command signal is input to the semiconductor IC at the write operation.

The second signal ‘YSPBC’ can be in synchronization with a clock signal ‘CLK’ that can be correspondent to a read command signal while the write operation is performed.

The third signal ‘WTSTBY’ can be input into a command decoder, wherein the command decoder can produce command signals, which can be related to the write operation, using the signal ‘WTSTBY’. The third signal ‘WTSTBY’ can be activated faster than the data driven to the global data line GIO, and can be inactivated after the driving of the data is terminated. The third signal ‘WTSTBY’ can be in synchronization with a clock signal ‘CLK’ that can be shifted by both the time of the additive latency (AL) and the column address strobe latency (CASL), and can be maintained at the activation state during the time of BL/2.

The control unit 30 can be configured to determine a first activation section, i.e., the activation section of the termination control signal ‘ENGIOTERM’, according to the first and third signals ‘WTS’ and ‘WTSTBY’ at the write operation. The beginning time of the first activation section can be set up faster than the point of time the data are driven to the global data line GIO by the WGIO driver 5.

The control unit 30 can also be configured to determine a second activation section, i.e., the activation section of the termination control signal ‘ENGIOTERM’, according to the first and second signals ‘WTS’ and ‘YSPBC’ at the read operation. The beginning time of the second activation section can be set up faster than the point of time the data are driven to the global data line GIO by the RGIO driver 3.

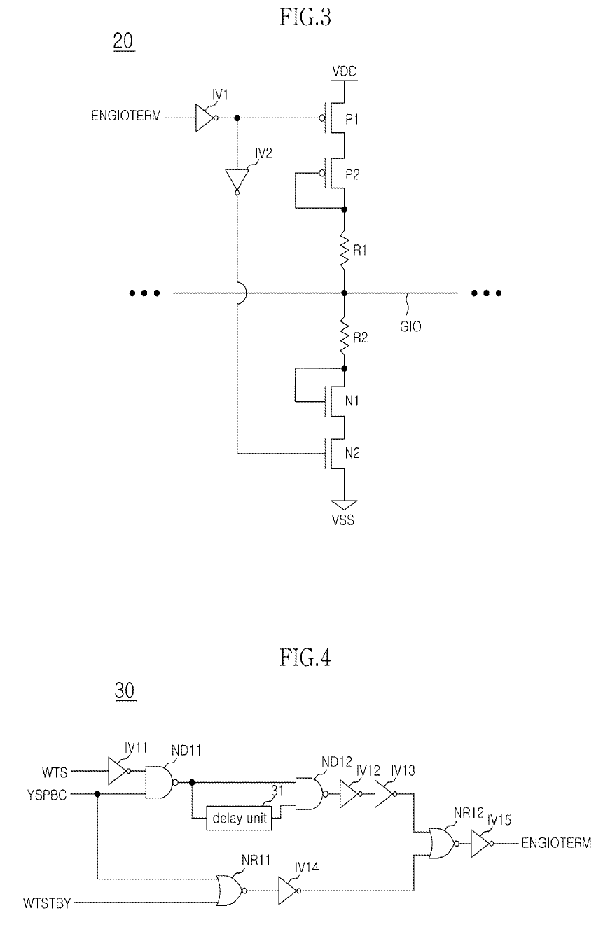

FIG. 3 is a schematic circuit diagram of an exemplary termination unit capable of being implemented in the semiconductor IC of FIG. 2 according to one embodiment. In FIG. 3, the termination unit 20 can be configured to include a resistor R1 coupled to the global data line GIO, a plurality of transistors P1 and P2 coupled between the power supply voltage VDD and the resistor R1, a resistor R2 coupled to the global data line GIO, a plurality of transistors P1 and P2 coupled between the ground voltage VSS and the resistor R2, and a plurality of inverters IV1 and IV2. Here, the transistors P2 and N1 can be used as active resistance elements and the resistors R1 and R2 can have substantially the same resistance values.

When the termination control signal ‘ENGIOTERM’ is activated, the global data line GIO can be terminated at the voltage level of VDD/2 through the resistance division because the transistors P1 and N2 can be turned ON, and the resistors R1 and R2 can have substantially the same resistance values.

FIG. 4 is a schematic circuit diagram of an exemplary control unit capable of being implemented in the semiconductor IC of FIG. 2 according to one embodiment. In FIG. 4, the control unit 30 can be configured to include first to fifth inverters IV11 to IV15, first and second NAND gates ND11 and ND12, first and second NOR gates NR11 and NR12, and a delay unit 32.

The control unit 30 can activate the termination control signal ‘ENGIOTERM’ when any one of the second and third signals ‘YSPBC’ and ‘WTSTBY’ is activated. The control unit 30 can make the termination control signal ‘ENGIOTERM’ have an activation section correspondent to the write operation, by enlarging the pulse width of the second signal ‘YSPBC’ through the delay unit 31 when the second signal ‘YSPBC’ is activated in a state where the first and third signals ‘WTS’ and ‘WTSTBY’ are inactivated at the read operation.

An exemplary operation of a semiconductor IC can include write and read operations, as described in detail below.

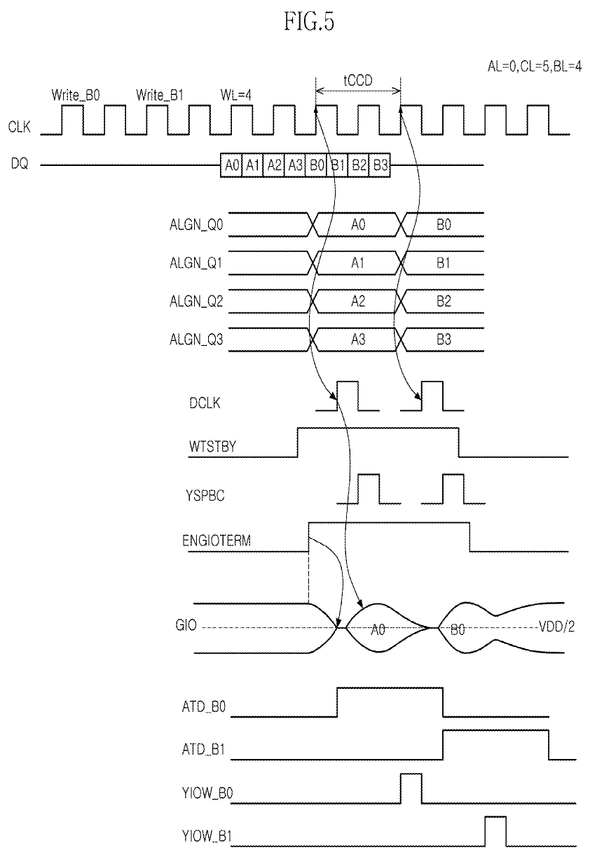

FIG. 5 is a timing chart representative of an exemplary write operation of a semiconductor IC according to one embodiment. In FIG. 5, write command signals ‘Write_B0’ and ‘Write_B1’ can be input, data can be input through pads DQ after the write latency WL, and then the input data can be arranged.

Next, the third signal ‘WTSTBY’ can be generated in synchronization with a clock signal ‘CLK’ that can be shifted by the time of the additive latency (AL) and the column address strobe latency (CASL), and can be maintained at the activation state during the time of BL/2. In addition, the first signal ‘WTS’ can be maintained at a high level while the write operation is carried out.

Then, the control unit 30 can activate the termination control signal ‘ENGIOTERM’ in response to an activation of the third signal ‘WTSTBY’ during the activation section that can be substantially the same as that of the third signal ‘WTSTBY’. In addition, the termination unit 20 can terminate the global data line GIO at a one-half level of the power supply voltage VDD, i.e., VDD/2, in response to the activation of the termination control signal ‘ENGIOTERM’.

Next, the data clock signal DCLK can be generated in synchronization with the first clock signal ‘CLK’ that can be first generated after the write command signals are input and the time of WL+BL/2 has passed. The second signal ‘YSPBC’ can be issued with a predetermined delay time due to a delay time caused by an internal circuit.

As a result, the WGIO driver 5 can drive the global data line GIO to a voltage level correspondent to the input data according to the data clock signal ‘DCLK’.

As shown in FIG. 5, the point of time the termination control signal ‘ENGIOTERM’ is activated can be faster than the data clock signal ‘DCLK’. Accordingly, the global data line GIO can be in a state where the voltage level of VDD/2 is maintained at the point of time a rising edge of the data clock signal ‘DCLK’ is issued, i.e., before the global data line GIO is driven by the WGIO driver 5.

The WGIO driver 5 can drive the global data line GIO from the one-half voltage level (VDD/2) to the power supply voltage (VDD) level or the ground voltage (VSS) level. For example, the swing width of the global data line GIO can be reduced to a one-half width.

Next, The data input driver 6 can drive and output the data of the global data line GIO according to control signals ‘ATD_B0’ and ‘ATD_B1’. The write driver 7 can drive the local data lines LIOT and LIOB to a voltage level that can be correspondent to an output signal of the data input driver 6 according to the control signals ‘YIOW_B0’ and ‘YIOW_B1’.

Then, The bit line sense amplifier 1 can sense and amplify the data on the local data lines LIOT and LIOB according to the column select signal ‘YS’, and can write the data to a memory cell coupled to itself.

At the read operation, the first and third signals ‘WTS’ and ‘WTSTBY’ can be maintained at an inactivation state, and the second signal ‘YSPBC’ can be generated in synchronization with the clock signal ‘CLK’, which is correspondent to the read command signal, according to the column address strobe signal.

Next, the control unit 30 can activate the termination control signal ‘ENGIOTERM’ in response to the second signal ‘YSPBC’ since the first and third signals ‘WTS’ and ‘WTSTBY’ can be maintained at the inactivation state. The activation of the second signal ‘YSPBC’, as a pulse signal, can be shorter than that of the third signal ‘WTSTBY’. Accordingly, the control unit 30 can make the termination control signal ‘ENGIOTERM’ have an activation section, which can be correspondent to the write operation, by enlarging the pulse width of the second signal ‘YSPBC’ through the delay unit 31.

Then, the termination unit 20 can terminate the global data line GIO at a one-half level of the power supply voltage of VDD, i.e., VDD/2, in response to the activation of the termination control signal ‘ENGIOTERM’.

Here, the point of time the termination control signal ‘ENGIOTERM’ is activated can be faster than the data clock signal ‘DCLK’. Accordingly, the global data line GIO can be in a state where the voltage level of VDD/2 is maintained at the point of time the enable signal ‘DBSAE’ is activated, i.e., before the global data line GIO is driven by the RGIO driver 3.

Next, the column select signal ‘YS’ can be generated by the second signal YSPBC. Then, the bit line sense amplifier 1 can sense and amplify the data from the memory cell coupled to itself, and can transfer the data to the local data lines LIOT and LIOB according to the column select signal ‘YS’. Next, the data bus sense amplifier 2 can output the data by sensing and amplifying the data loaded on the local data lines LIOT and LIOB

As a result, the RGIO driver 3 can drive the global data line GIO from the one-half voltage level (VDD/2) to the power supply voltage (VDD) level or the ground voltage (VSS) level according to an output signal of the data bus sense amplifier 2. For example, since the swing width of the global data line GIO can be reduced to a one-half width, the data transmission rate can be improved at the read operation.

Here, the multiplexer 4 can selectively output the data loaded on the global data line GIO in compliance with the data output modes of x4, x8 and x16 according to the multiplexing control signal ‘MUX_CONTROL’ that can have a delay timing compared to the enable signal ‘DBSAE’.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claim is:

1. A data line termination circuit in a semiconductor integrated circuit, comprising:
a data line;
a control unit for generating a termination control signal activated during a time section that includes a driving section in which data is driven to the data line; and
a termination unit for terminating the data line to a predetermined voltage level in response to the termination control signal.

2. The data line termination circuit of claim 1, wherein the control unit is configured to generate the termination control signal and activation period of the termination control signal are different from each other in write and read operations.

3. The data line termination circuit of claim 1, wherein the control unit is configured to activate the termination control signal before the data is driven to the data line.

4. The data line termination circuit of claim 1, wherein the control unit is configured to determine an activation section of the termination control signal according to at least one of a plurality of timing signals related to a write or read operation.

5. The data line termination circuit of claim 4, wherein each of the plurality of the timing signals includes:
a first signal activated during an activation of the write operation;
a second signal generated according to a column address strobe signal and used for generating a column select signal; and
a third signal used for generating command signals related to the write operation in a command decoder.

6. The data line termination circuit of claim 5, wherein the control unit is configured to output the third signal as the termination control signal when the third signal is activated and to output the termination control signal when the second signal is activated, and the third signal has a pulse width larger than a pulse width of the second signal.

7. The data line termination circuit of claim 5, wherein the second signal is in synchronization with a clock signal issued after a time period of a write latency and a one-half of a burst length has passed, and the third signal is in synchronization with a clock signal shifted by a time period of an additive latency and a column address strobe latency after the write command signal.

8. The data line termination circuit of claim 1, wherein the data line includes a global data line used for both the read operation and the write operation.

9. The data line termination circuit of claim 1, wherein the termination unit is configured to terminate the data line to a one-half level of a power supply voltage in response to an activation of the termination control signal.

10. The data line termination circuit of claim 9, wherein the termination unit includes:
a first resistor coupled to the global data line;
a first switching unit for coupling the first resistor to a power supply voltage terminal in response to the activation of the termination control signal;
a second resistor coupled to the global data line; and
a second switching unit for coupling the second resistor to a ground voltage terminal in response to the activation of the termination control signal.

11. The data line termination circuit of claim 1, wherein the time section includes margin sections taken before and after the driving section in which the data is driven to the data line.

12. A data line termination circuit in a semiconductor integrated circuit, comprising:
a data line;
a driver for driving the data line to a voltage level correspondent to input data received from an external circuit at a write operation;
a control unit for generating a termination control signal activated during a time section that includes a driving section of the driver in which the data is driven to the data line; and
a termination unit for terminating the data line to a predetermined voltage level in response to the termination control signal.

13. The data line termination circuit of claim 12, wherein the control unit is configured to activate the termination control signal before the driver drives the data to the data line.

14. The data line termination circuit of claim 12, wherein the control unit is configured to determine an activation section of the termination control signal according to a timing signal generated with a predetermined latency after a write command signal.

15. The data line termination circuit of claim 14, wherein the timing signal is a clock signal shifted by a time of an additive latency and a column address strobe latency after the write command signal.

16. The data line termination circuit of claim 12, wherein the data line includes a global data line used for both the read operation and the write operation.

17. The data line termination circuit of claim 12, wherein the termination unit is configured to terminate the data line to a one-half level of a power supply voltage in response to an activation of the termination control signal.

18. The data line termination circuit of claim 17, wherein the termination unit includes:
a first resistor coupled to the global data line;
a first switching unit for coupling the first resistor to a power supply voltage terminal in response to the activation of the termination control signal;
a second resistor coupled to the global data line; and
a second switching unit for coupling the second resistor to a ground voltage terminal in response to the activation of the termination control signal.

19. The data line termination circuit of claim 12, wherein the time section includes margin sections that are taken before and after the driving section in which the data is driven to the data line.

20. A data line termination circuit in a semiconductor integrated circuit, comprising:
a data line;
a driver for driving the data line to a voltage level correspondent to data from a memory cell at a read operation;
a control unit for generating a termination control signal activated during a time section that includes a driving section of the driver in which the data is driven to the data line; and
a termination unit for terminating the data line to a predetermined voltage level in response to the termination control signal.

21. The data line termination circuit of claim 20, wherein the control unit is configured to activate the termination control signal before the driver drives the data to the data line.

22. The data line termination circuit of claim 20, wherein the control unit is configured to determine an activation section of the termination control signal using a timing signal generated according to a column address strobe signal.

23. The data line termination circuit of claim 22, wherein the control unit is configured to output a signal as the termination control signal produced by increasing a pulse width of the timing signal.

24. The data line termination circuit of claim 20, wherein the data line includes a global data line used for both the read operation and the write operation.

25. The data line termination circuit of claim 20, wherein the termination unit is configured to terminate the data line to a one-half level of a power supply voltage in response to an activation of the termination control signal.

26. The data line termination circuit of claim 25, wherein the termination unit includes:
a first resistor coupled to the global data line;
a first switching unit for coupling the first resistor to a power supply voltage terminal in response to the activation of the termination control signal;
a second resistor coupled to the global data line; and
a second switching unit for coupling the second resistor to a ground voltage terminal in response to the activation of the termination control signal.

27. The data line termination circuit of claim 20, wherein the time section includes margin sections taken before and after the driving section in which the data is driven to the data line.

28. A data line termination circuit in a semiconductor integrated circuit, comprising:
a data line;
a first driver for driving the data line to a voltage level correspondent to input data received from an external circuit at a write operation;
a second driver for driving the data line to a voltage level correspondent to data from a memory cell at a read operation;
a control unit for generating a termination control signal activated during a time section that includes a driving section of the first and second driver in which the data is driven to the data line; and
a termination unit for terminating the data line to a predetermined voltage level in response to the termination control signal.

29. The data line termination circuit of claim 28, wherein the control unit is configured to activate the termination control signal before the driver drives the data to the data line.

30. The data line termination circuit of claim 28, wherein the control unit is configured to determine an activation section of the termination control signal according to a first timing signal generated with a predetermined latency after a write command signal at the write operation.

31. The data line termination circuit of claim 30, wherein the first timing signal is a clock signal shifted by a time of an additive latency and a column address strobe latency after the write command signal.

32. The data line termination circuit of claim 28, wherein the control unit is configured to determine an activation section of the termination control signal using the second timing signal generated according to a column address strobe signal at the read operation.

33. The data line termination circuit of claim 32, wherein the control unit is configured to output a signal as the termination control signal at the read operation produced by increasing a pulse width of the second timing signal.

34. The data line termination circuit of claim 28, wherein the data line includes a global data line used for both the read operation and the write operation.

35. The data line termination circuit of claim 28, wherein the termination unit is configured to terminate the data line to a one-half level of a power supply voltage in response to an activation of the termination control signal.

36. The data line termination circuit of claim 35, wherein the termination unit includes:
a first resistor coupled to the global data line;
a first switching unit for coupling the first resistor to a power supply voltage terminal in response to the activation of the termination control signal;
a second resistor coupled to the global data line; and
a second switching unit for coupling the second resistor to a ground voltage terminal in response to the activation of the termination control signal.

37. The data line termination circuit of claim 28, wherein the time section includes margin sections taken before and after the driving section in which the data is driven to the data line.

38. A method for terminating a data line in a semiconductor integrated circuit, comprising:
checking whether a write command signal or a read command signal is input; and
terminating a data line to a predetermined voltage level during a time section that includes a driving section in which data are driven to the data line according to the write or read command signal when the write or read command signal is input.

39. The method of claim 38, wherein the terminating of the data line starts to terminate the data line before the data is driven to the data line according to the write command signal at a write operation.

40. The method of claim 39, wherein the time section at the write operation is determined by a signal in synchronization with a clock signal shifted by a time of an additive latency and a column address strobe latency.

41. The method of claim 38, wherein the terminating of the data line starts to terminate the data line before the data is driven to the data line according to the read command signal at a read operation.

42. The method of claim 41, wherein the time section at the read operation is determined by a signal used for generating a column select signal generated according to a column address strobe signal.

43. The method of claim 38, wherein the predetermined voltage level for the terminating the data line is a one-half level of a power supply voltage.

44. A method for terminating a data line in a semiconductor integrated circuit, wherein the semiconductor integrated circuit includes a data line and a driver to drive the data line to a voltage level correspondent to input data received from an external circuit according to a write command signal, the method comprising:
checking whether the write command signal is input; and
terminating the data line to a predetermined voltage level before a driving operation of the driver when the write command signal is input.

45. The method of claim 44, wherein the terminating of the data line is determined by a signal in synchronization with a clock signal shifted by a time of an additive latency and a column address strobe latency.

46. The method of claim 44, wherein the predetermined voltage level for the terminating the data line is a one-half level of a power supply voltage.
